(19) United States
(12) Patent Application Publication
(10) Pub. No.: US 2025/0091173 A1
(43) Pub. Date: Mar. 20, 2025

(54) Wafer Thinning System and Thinning Method

(71) Applicant: Guangzhou Aifo Light Communication Technology Co., Ltd, Guangzhou (CN)

(72) Inventors: Guoqiang Li, Guangzhou (CN); Xinyan Yi, Guangzhou (CN)

(21) Appl. No.: 18/430,701

(22) Filed: Feb. 2, 2024

(30) Foreign Application Priority Data
Sep. 15, 2023 (CN) 202311194843.5

(51) Int. Cl. B24B 7/06; B24B 51/00

(52) U.S. Cl. CPC B24B 7/06; B24B 51/00

(57) ABSTRACT

The invention relates to the technical field of wafer processing, and specifically discloses a wafer thinning system and a thinning method. The system includes a first transfer mechanism, a first conveying mechanism and a second transfer mechanism, as well as a rough grinding mechanism, a fine grinding mechanism and a detection mechanism disposed on the first conveying mechanism. The system further includes carrying mechanisms, a second conveying mechanism, and a controller. The controller is configured to control the first conveying mechanism to convey the carrying mechanisms and control the rough grinding mechanism, the fine grinding mechanism and the detection mechanism to sequentially perform rough grinding, fine grinding and thickness detection on the wafers. The system can implement rough grinding, fine grinding and thickness detection for the wafers, thereby implementing continuous thinning of the wafer and increasing the yield of wafer thinning.

### CROSS REFERENCE TO RELATED APPLICATIONS

The present claims the benefit of Chinese Patent Application No. 202311194843.5 filed on Sep. 15, 2023, the contents of which are incorporated herein by reference in their entirety.

### TECHNICAL FIELD

The invention relates to the technical field of wafer processing, and specifically relates to a wafer thinning system and a thinning method.

### BACKGROUND

During chip production, it is necessary to thin a wafer to a specified thickness before slicing and scribing. In a related technology, a two-step grinding operation is required for thinning of the wafer. In the first step, a rough grinding mechanism provided with a large-gravel rough grinding wheel is required for quickly thinning the wafer; and in the second step, a fine grinding mechanism provided with a small-gravel fine grinding wheel is required for high-precision thinning of the wafer, such that the wafer is polished and ground to a preset thickness. The existing two grinding steps are separately and independently performed and require step-by-step detection, significantly restricting the wafer thinning efficiency.

At present, there is still no effective technical solution to solve the foregoing problem.

### SUMMARY

The invention is intended to provide a wafer thinning system to improve the wafer thinning efficiency.

According to a first aspect, the invention provides a wafer thinning system, where the wafer thinning system includes a first transfer mechanism, a first conveying mechanism and a second transfer mechanism arranged in sequence, as well as a rough grinding mechanism, a fine grinding mechanism and a detection mechanism that are arranged in sequence on the first conveying mechanism;
the wafer thinning system further includes a plurality of carrying mechanisms for carrying wafers, a second conveying mechanism having a head end and a tail end connected to the first transfer mechanism and the second transfer mechanism, and a controller;
the controller is configured to control the first conveying mechanism to convey the plurality of carrying mechanisms in a stepping manner and control the rough grinding mechanism, the fine grinding mechanism and the detection mechanism to sequentially perform rough grinding, fine grinding and thickness detection on the wafers on the carrying mechanisms; and
the controller is further configured to control, when a wafer has a thickness exceeding a preset thickness range, the second transfer mechanism, the second conveying mechanism and the first transfer mechanism to cooperate with each other to transfer a carrying mechanism carrying the wafer having a thickness exceeding the preset thickness range back to a feeding end of the first conveying mechanism, and to control the fine grinding mechanism to perform fine grinding again on the wafer on the carrying mechanism and control the detection mechanism to perform thickness detection again on the wafer on the carrying mechanism when the carrying mechanism is conveyed on the first conveying mechanism in a stepping manner.

The wafer thinning system in the invention is provided with the rough grinding mechanism, the fine grinding mechanism and the detection mechanism in sequence on the first conveying mechanism, such that the wafers on the plurality of carrying mechanisms conveyed in a stepping manner by the first conveying mechanism can undergo rough grinding, fine grinding and thickness detection in sequence, and thus the wafers are continuously thinned. In addition, when a wafer has a thickness exceeding the preset thickness range, the wafer is returned to the feeding end of the first conveying mechanism through a returning function achieved under the cooperation of the second transfer mechanism, the second conveying mechanism and the first transfer mechanism, such that the wafer on the carrying mechanism undergo secondary fine grinding, so as to increase the yield of wafer thinning.

In the wafer thinning system, the detection mechanism includes a jacking and separating assembly and a detection assembly.

The jacking and separating assembly is configured to jack and separate the wafers on the carrying mechanisms located in the detection mechanism for thickness detection of the wafers in cooperation with the detection assembly.

According to the wafer thinning system in this example, the jacking and separating assembly in the detection mechanism is used to separate the wafers on the carrying mechanisms first, and then the detection assembly is used to perform thickness detection on the wafers, to ensure that the thickness data obtained is more precise, such that reliability of thickness detection is improved, and thus the yield of wafer thinning is further increased.

In the wafer thinning system, the carrying mechanisms are each provided with a plurality of through holes; and the jacking and separating assembly includes a plurality of ejector pins capable of passing through the through holes and a first elevating mechanism configured to drive the ejector pins to move up and down;
the controller is configured to control the first elevating mechanism to drive the ejector pins to move up to separate the wafers according to preset height information, so as to allow the detection assembly to measure thickness deviation information of the wafers.

In this example, the controller can determine whether the thickness of the wafers is in accordance with a preset thickness according to the thickness deviation information, that is, determine whether the thickness of the wafers is within the preset thickness range.

In the wafer thinning system, the detection assembly includes a detection base plate, a plurality of detection electrodes fixed to a bottom surface of the detection base plate, and an elastic piece fixedly arranged below the detection base plate; a gap is reserved between the elastic piece and the detection electrodes.
the controller is configured to obtain thickness deviation information of the wafers through calculation according to capacitance generated by the detection electrodes when the elastic piece generates deformation while pressing the wafer.

In the wafer thinning system, the controller is further configured to generate compensation thickness information according to the thickness deviation information when the thickness deviation information indicates an excessive thickness deviation, and to control the fine grinding mechanism to perform fine grinding again on a corresponding wafer according to the compensation thickness information.

In the wafer thinning system, the wafer thinning system further includes two lifting assemblies that are arranged below the rough grinding mechanism and the fine grinding mechanism, respectively, and are configured to lift the carrying mechanisms on the first conveying mechanism to implement rough grinding in cooperation with the rough grinding mechanism and to implement fine grinding in cooperation with the fine grinding mechanism, respectively.

In the wafer thinning system, the wafer thinning system further includes blowing assemblies; the blowing assemblies are arranged on one sides of the lifting assembly; and the controller is configured to control the blowing assemblies to blow the lifting assemblies that are not in a lifting state.

In the wafer thinning system, the carrying mechanisms each include an electronic tag; the detection mechanism includes a tag editor, and the rough grinding mechanism includes a tag
recognizer; and

the controller is further configured to mark an electronic tag of the carrying mechanism on which the wafer having a thickness exceeding the preset thickness range is located based on the tag editor, so as to allow the rough grinding mechanism to skip rough grinding by recognizing the electronic tag based on the tag recognizer.

In the wafer thinning system, the first transfer mechanism is in consistence with the second transfer mechanism; the first transfer mechanism includes an elevating assembly and a bidirectional conveying mechanism; and the elevating assembly is configured to drive the bidirectional conveying mechanism to move up and down such that one end of the bidirectional conveying mechanism connects to the first conveying mechanism or the second conveying mechanism.

According to a second aspect, the invention further provides a thinning method of a wafer thinning system. The thinning method is applied to the wafer thinning system. The wafer thinning system includes a first transfer mechanism, a first conveying mechanism and a second transfer mechanism arranged in sequence, as well as a rough grinding mechanism, a fine grinding mechanism and a detection mechanism that are arranged in sequence on the first conveying mechanism; the wafer thinning system further includes a plurality of carrying mechanisms for carrying wafers, and a second conveying mechanism having a head end and a tail end connected to the first transfer mechanism and the second transfer mechanism;
the thinning method includes the following steps:
controlling the first conveying mechanism to convey the plurality of carrying mechanisms in a stepping manner and controlling the rough grinding mechanism, the fine grinding mechanism and the detection mechanism to sequentially perform rough grinding, fine grinding and thickness detection on the wafers on the carrying mechanisms; and
when a wafer has a thickness exceeding a preset thickness range, controlling the second transfer mechanism, the second conveying mechanism and the first transfer mechanism to cooperate with each other to transfer a carrying mechanism carrying the wafer having a thickness exceeding the preset thickness range back to a feeding end of the first conveying mechanism, and controlling the fine grinding mechanism to perform fine grinding again on the wafer on the carrying mechanism and controlling the detection mechanism to perform thickness detection again on the wafer on the carrying mechanism when the carrying mechanism is conveyed on the first conveying mechanism in a stepping manner.

The thinning method of a wafer thinning system in the invention can implement rough grinding, fine grinding and thickness detection in sequence for the wafers on the carrying mechanisms, and thus the wafers are continuously thinned. In addition, when a wafer has a thickness exceeding the preset thickness range, the wafer is returned to the feeding end of the first conveying mechanism through a returning function achieved under the cooperation of the second transfer mechanism, the second conveying mechanism and the first transfer mechanism, such that the wafer on the carrying mechanism undergoes secondary fine grinding, so as to increase the yield of wafer thinning.

It can be learned from the above that the invention provides a wafer thinning system and a thinning method, where the wafer thinning system is provided with the rough grinding mechanism, the fine grinding mechanism and the detection mechanism in sequence on the first conveying mechanism, such that the wafers on the plurality of carrying mechanisms conveyed in a stepping manner by the first conveying mechanism can undergo rough grinding, fine grinding and thickness detection in sequence, and thus the wafers are continuously thinned. In addition, when a wafer has a thickness exceeding the preset thickness range, the wafer is returned to the feeding end of the first conveying mechanism through a returning function achieved under the cooperation of the second transfer mechanism, the second conveying mechanism and the first transfer mechanism, such that the wafer on the carrying mechanism undergo secondary fine grinding, so as to increase the yield of wafer thinning.

### BRIEF DESCRIPTION OF FIGURES

FIG. 1 is a schematic structural diagram of a wafer thinning system in an embodiment of the invention.

FIG. 2 is a schematic structural diagram showing cooperation of a first conveying mechanism and a rough grinding mechanism.

FIG. 3 is a schematic structural diagram of a first conveying mechanism at a rough grinding mechanism.

FIG. 4 is a schematic structural diagram of a carrying mechanism.

FIG. 5 is a schematic structural diagram of a first conveying mechanism at a detection mechanism.

FIG. 6 is a schematic structural diagram of a wafer being jacked by a jacking and separating assembly.

FIG. 7 is a schematic electrical control structural diagram of a wafer thinning system provided in an embodiment of the invention.

FIG. 8 is a flowchart of a thinning method of a wafer thinning system provided in an embodiment of the invention.

Reference numerals: 1. first transfer mechanism; 2. first conveying mechanism; 3. second transfer mechanism; 4. rough grinding mechanism; 5. fine grinding mechanism; 6. detection mechanism; 7. carrying mechanism; 8. second conveying mechanism; 9. controller; 10. limiting mechanism; 11. lifting assembly; 12. blowing assembly; 13. tag editor; 14. tag recognizer; 61. jacking and separating assembly; 62. detection assembly; 71. carrying table; 72. workpiece groove; 73. electronic tag; 101. limiting and elevating mechanism; 102. limiting plate; 111. lifting driving mechanism; 112. lifting plate; 611. ejector pin; 612. first elevating mechanism; 621. detection base plate; 622. detection electrode; 623. elastic piece; and 711. through hole.

### DETAILED DESCRIPTION

The embodiments of the invention are described in detail below. Examples of the embodiments are shown in the accompanying drawings, and reference numerals that are the same or similar always indicate the same or similar elements or elements with the same or similar functions. The embodiments described below with reference to the accompanying drawings are illustrative and merely for explaining the invention, and cannot be construed as a limitation on the invention.

In the description of the invention, the orientations or positional relationships indicated by the terms such as “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside”, “clockwise”, and “counterclockwise” are based on the orientations or positional relationships as shown in the accompanying drawings. These terms are merely for ease and brevity of description of the embodiments of the invention rather than indicating or implying that the apparatuses or components mentioned must have specific orientations or must be constructed or manipulated according to specific orientations, and therefore shall not be construed as a limitation on embodiments of the invention. In addition, terms “first” and “second” are only intended for description, but cannot be construed as indicating or implying relative importance or implicitly indicating the number of the specified technical features. Therefore, a feature limited by “first” and “second” can explicitly or implicitly include one or more such features. In the description of the invention, “a plurality of” means two or more, unless otherwise explicitly defined.

In the description of the invention, it should be noted that unless otherwise explicitly specified and defined, the understanding of terms “installed”, “linked” and “connected” should be generalized, for example, the terms may be fixed connected, detachably connected or integrally connected; the terms may be mechanically connected, electrically connected or communicating with each other; and the terms may be directly linked, indirectly linked through an intermediate, communication between the interiors of two elements or an interactive relation between two elements. Those of ordinary skill in the art could understand the specific meanings of the above terms in the invention according to specific situations.

In the invention, unless otherwise explicitly specified or defined, the first feature being “on” or “beneath” the second feature may include the first feature being in direct contact with the second feature or the first feature being in contact with the second feature through another feature rather than in direct contact with the second feature. Moreover, the first feature being “on”, “over” and “above” the second feature may include the first feature being over and above the second feature, or only represents that the level of the first feature is higher than the level of the second feature. The first feature being “beneath”, “under” and “below” the second feature may include the first feature being under and below the second feature, or only represents that the level of the first feature is lower than the level of the second feature.

The disclosure hereinafter provides a lot of different embodiments or examples to implement the different structures of the invention. In order to simplify the disclosure of the invention, the parts and configurations of the specific examples are described hereinafter. Of course, they are only illustrative rather than intended to limit the invention. In addition, the invention may repeat reference numbers or reference letters in different examples, and such repetition is intended for simplification and clarification rather than indicates the relation between the various embodiments and/or configurations discussed. In addition, although the invention provides the examples of various specific processes and materials, those of ordinary skill in the art can realize the application of other processes and/or the use of other materials.

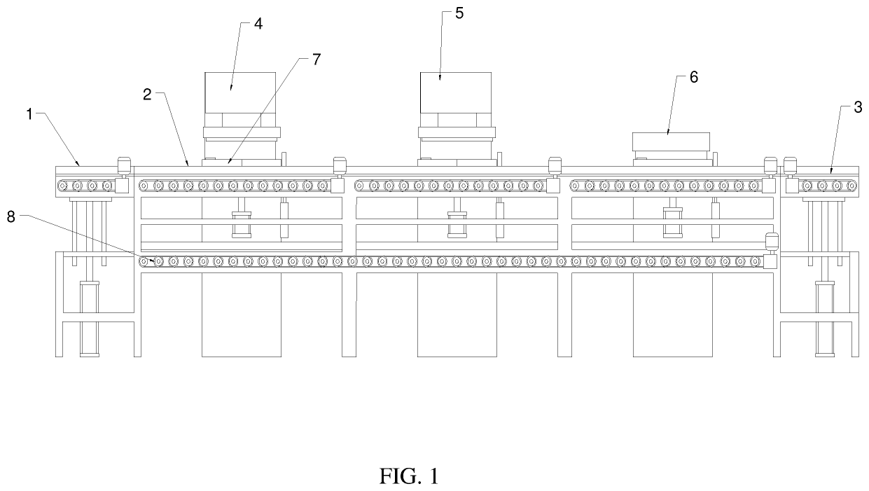

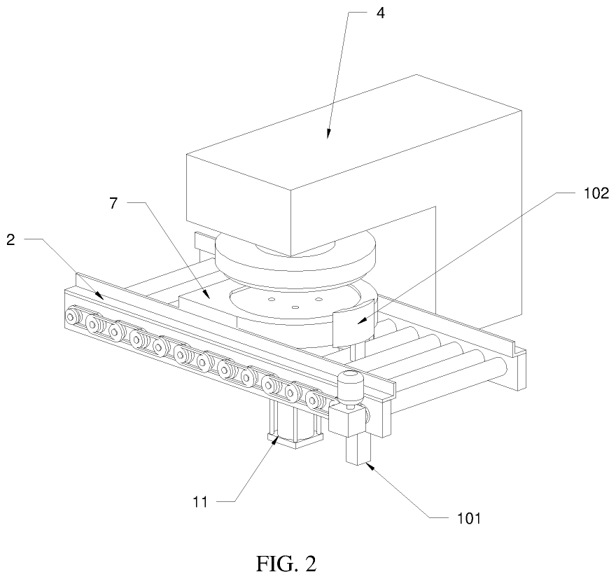

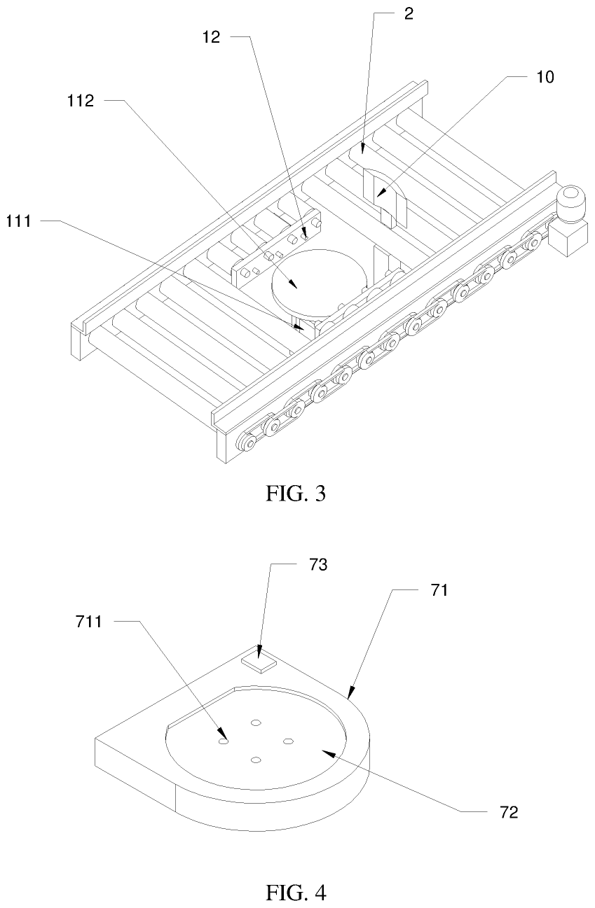

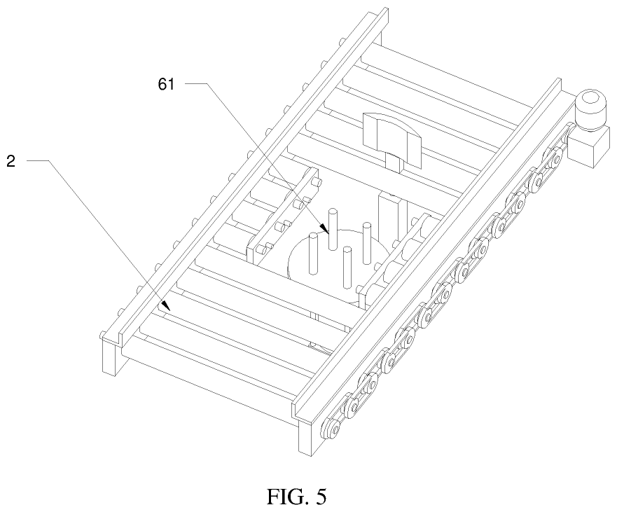

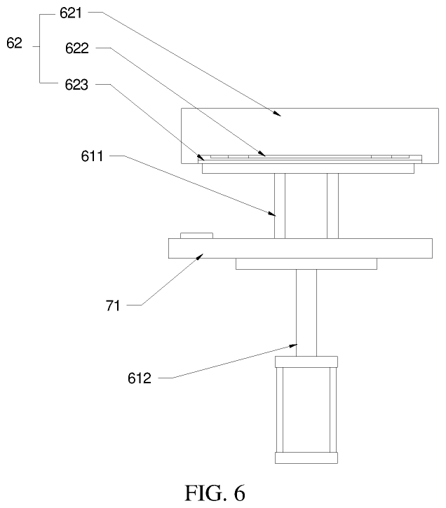

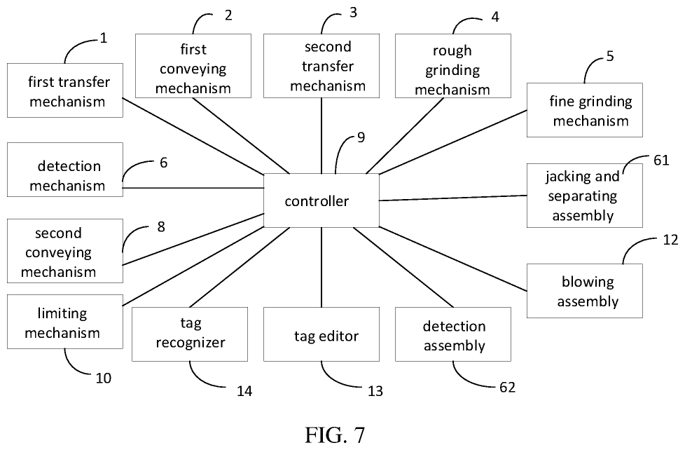

According to a first aspect, referring to FIG. 1 to FIG. 7, some embodiments of the invention provide a wafer thinning system. The wafer thinning system includes a first transfer mechanism 1, a first conveying mechanism 2 and a second transfer mechanism 3 arranged in sequence, as well as a rough grinding mechanism 4, a fine grinding mechanism 5 and a detection mechanism 6 that are arranged in sequence on the first conveying mechanism 2.

The wafer thinning system further includes a plurality of carrying mechanisms 7 for carrying wafers, a second conveying mechanism 8 having a head end and a tail end connected to the first transfer mechanism 1 and the second transfer mechanism 3, and a controller 9.

The controller 9 is configured to control the first conveying mechanism 2 to convey the plurality of carrying mechanisms 7 in a stepping manner and control the rough grinding mechanism 4, the fine grinding mechanism 5 and the detection mechanism 6 to sequentially perform rough grinding, fine grinding and thickness detection on the wafers on the carrying mechanisms 7.

The controller 9 is further configured to control, when a wafer has a thickness exceeding a preset thickness range, the second transfer mechanism 3, the second conveying mechanism 8 and the first transfer mechanism 1 to cooperate with each other to transfer a carrying mechanism 7 carrying the wafer having a thickness exceeding the preset thickness range back to a feeding end of the first conveying mechanism 2, and to control the fine grinding mechanism 5 to perform fine grinding again on the wafer on the carrying mechanism 7 and control the detection mechanism 6 to perform thickness detection again on the wafer on the carrying mechanism 7 when the carrying mechanism 7 is conveyed on the first conveying mechanism 2 in a stepping manner.

Specifically, the rough grinding mechanism 4 and the fine grinding mechanism are both configured to grind to thin the wafers, such that the wafers each have expected required thickness and surface smoothness. Rough grinding is a rough processing step for quickly thinning the wafers, in which a grinding wheel with a large roughness is used to reduce the thickness of each wafer to near a target thickness. Fine grinding is a fine processing step for implementing high-precision thinning of the wafers, in which a grinding wheel with a small roughness is used to reduce the thickness of each wafer to a target thickness to allow each wafer to have a qualified surface smoothness.

More specifically, the carrying mechanisms 7 are conveyed in a stepping manner based on the first conveying mechanism 2 so as to pass through the rough grinding mechanism 4, the fine grinding mechanism 5 and the detection mechanism 6 in sequence on the first conveying mechanism 2 and undergo corresponding operations. Therefore, in embodiments of the invention, a distance between the rough grinding mechanism 4 and the fine grinding mechanism 5 is the same as a distance between the fine grinding mechanism 5 and the detection mechanism 6, such that when the plurality of carrying mechanisms 7 are conveyed by the first conveying mechanism 2, the carrying mechanisms 7 can move to next stations in a unified stepping stroke. For example, one carrying mechanism 7 moves from the rough grinding mechanism 4 to the fine grinding mechanism 5 for fine grinding, and another carrying mechanism 7 moves from the fine grinding mechanism 5 to the detection mechanism 6 for thickness detection. In this way, the wafer thinning system in embodiments of the invention implement high-efficiency continuous thinning of wafers.

More specifically, in these embodiments of the invention, the rough grinding mechanism 4 and the fine grinding mechanism 5 are both a vertically elevated sanding wheel grinding apparatus in which a height of a sanding wheel is changed under driving of a linear drive module, such that an upper surface of a wafer is ground multiple times to reduce the thickness of the wafer. Therefore, the rough grinding mechanism 4 and the fine grinding mechanism 5 both thin the wafer based on a preset elevating stroke. The thicknesses of the wafers that have been subjected to rough grinding and fine grinding necessarily meet the requirements of rough grinding (less than a thickness set for rough grinding). However, due to position offset of the carrying mechanisms 7, bottom abrasion of the carrying mechanisms 7, abrasion of sanding wheels, and height deviation of the rough grinding mechanism 4 and the fine grinding mechanism 5, the thicknesses of the wafers may not necessarily meet the requirements of fine grinding (a deviation between the thickness of the wafer and a thickness set for fine grinding is greater than an expected value). Therefore, these wafers are defective products. If the thicknesses of the wafers are greater than the expected value, such wafers can be ground and thinned again to increase the yield of products. If the thicknesses of the wafers are less than the expected value, such wafers are considered rejects for processing failures. The wafer thinning system in embodiments of the invention are intended to implement secondary fine grinding by returning and processing such wafers so as to increase the yield of wafer thinning. The wafers that have been subjected to rough grinding and fine grinding do not need secondary rough grinding. Therefore, the controller 9 controls the rough grinding mechanism 4 to skip rough grinding for the wafers on the carrying mechanisms 7 that are returned, so as to reduce device energy consumption.

It should be noted that a conveying action of a next stage is performed after rough grinding, fine grinding and thickness detection in a current stage of the first conveying mechanism 2 are completed, thereby ensuring orderly processing at all processing stations.

It should be noted that the side of the first transfer mechanism 1 facing away from the first conveying mechanism 2 is provided with a feeding mechanism. The feeding mechanism is configured to feed a carrying mechanism 7 carrying a wafer that has not been thinned toward the first transfer mechanism 1. The side of the second transfer mechanism 3 facing away from the first conveying mechanism 2 is provided with a discharging mechanism. The discharging mechanism is configured to receive the carrying mechanism carrying a qualified thinned wafer or a reject that is fed from the second transfer mechanism 3. The feeding mechanism and the discharging mechanism are preferably roller conveyors.

It should be noted that the first transfer mechanism 1, the first conveying mechanism 2, the second transfer mechanism 3, the rough grinding mechanism 4, the fine grinding mechanism 5 and the detection mechanism 6 are all electrically connected to the controller 9.

More specifically, the controller 9 can control a conveying direction of the second transfer mechanism 3 for the carrying mechanism 7 carrying the wafer according to a thickness detection result of the wafer, control the second transfer mechanism 3 to convey the carrying mechanism 7 to the discharge mechanism when the thickness of the wafer meets the requirements of a preset thickness, control the second transfer mechanism 3 to convey the carrying mechanism 7 to the second conveying mechanism 8 when the thickness of the wafer exceeds the preset thickness range, and uses the second conveying mechanism 8 and the first transfer mechanism to return the carrying mechanism 7 to the feeding end of the first conveying mechanism 2 for stepping conveying again.

It should be noted that to ensure that the returned carrying mechanism 7 meets the requirements of stepping conveying, before the carrying mechanism 7 is returned to the first conveying mechanism 2, the feeding mechanism stops conveying a new carrying mechanism 7 to the first transfer mechanism 1 to complete the stepping conveying of the carrying mechanism 7 in cooperation with the first conveying mechanism 2.

The wafer thinning system in embodiments of the invention is provided with the rough grinding mechanism 4, the fine grinding mechanism 5 and the detection mechanism 6 in sequence on the first conveying mechanism 2, such that the wafers on the plurality of carrying mechanisms 7 conveyed in a stepping manner by the first conveying mechanism 2 can undergo rough grinding, fine grinding and thickness detection in sequence, and thus the wafers are continuously thinned. In addition, when a wafer has a thickness exceeding the preset thickness range, the wafer is returned to the feeding end of the first conveying mechanism 2 through a returning function achieved under the cooperation of the second transfer mechanism 3, the second conveying mechanism 8 and the first transfer mechanism 1, such that the wafer on the corresponding carrying mechanism 7 undergoes secondary fine grinding, so as to increase the yield of wafer thinning.

In some preferred embodiments, the carrying mechanisms 7 each include a carrying table 71. The carrying tables 71 are each provided with a workpiece groove 72 for placing a wafer. The carrying tables 71 are each internally provided with an electrostatic adsorption assembly (not shown) for fixing the wafer.

Specifically, the electrostatic adsorption assemblies can fix the wafers to the carrying tables 71, thereby preventing influence on thinning effect caused by position offset of the wafers during conveying or grinding.

More specifically, the first conveying mechanism 2 is provided with a power supply assembly for supplying power to the electrostatic adsorption assemblies. Alternatively, the carrying mechanisms 7 are each provided with a power supply for supplying power to the electrostatic adsorption assemblies. The electrostatic adsorption assemblies are preferably supplied with power in the latter manner.

In some preferred embodiments, the detection mechanism 6 includes a jacking and separating assembly 61 and a detection assembly 62.

The jacking and separating assembly 61 is configured to jack and separate the wafers on the carrying mechanisms 7 located in the detection mechanism 6 for thickness detection of the wafers in cooperation with the detection assembly 62.

Specifically, it can be learned from the foregoing description that bottom abrasion of the carrying mechanisms 7 may also affect the wafer thinning effect, and thickness data obtained through thickness detection performed on the wafers on the carrying mechanisms 7 by directly using devices such as a distance sensor lacks reliability. Therefore, according to the wafer thinning system in embodiments of the invention, the jacking and separating assembly 61 in the detection mechanism 6 is used to separate the wafers on the carrying mechanisms 7 first, and then the detection assembly 62 is used to perform thickness detection on the wafers, to ensure that the thickness data obtained is more precise, such that reliability of thickness detection is improved, and thus the yield of wafer thinning is further increased.

In some preferred embodiments, the carrying mechanisms 7 are each provided with a plurality of through holes 711. The jacking and separating assembly 61 includes a plurality of ejector pins 611 capable of passing through the through holes 711 and a first elevating mechanism 612 configured to drive the ejector pins 611 to move up and down.

The controller 9 is configured to control the first elevating mechanism 612 to drive the ejector pins 611 to move up to separate the wafers according to preset height information, so as to allow the detection assembly 62 to measure thickness deviation information of the wafers.

Specifically, when the carrying mechanisms 7 move to a position below the detection mechanism 6, the controller 9 controls the first elevating mechanism 612 to drive the ejector pins 611 to move up to pass through the through holes 711 in the carrying mechanisms 7 to lean against bottom surfaces of the wafers, and thus the wafers are separated and lifted to a height corresponding to the preset height information, i.e., moved to a preset detection position. Then the detection assembly 62 acquires thickness data of the wafers at the detection position and analyzes a difference between the thicknesses of the wafers and the preset thickness (the preset thickness range is a range determined based on the preset thickness in combination with a thickness tolerance), that is, thickness deviation information. The controller 9 can determine whether the thicknesses of the wafers are in accordance with the preset thickness according to the thickness deviation information, that is, determine whether the thicknesses of the wafers are within the preset thickness range.

More specifically, the ejector pins 611 passing through the through holes 711 can lock positions of the carrying mechanisms 7 on the first conveying mechanism 2, so as to avoid displacement of the carrying mechanisms 7 during detection, otherwise the displacement may cause that the wafers cannot be placed on the carrying mechanisms 7 again after the detection is completed.

In some preferred embodiments, the detection assembly 62 includes a detection base plate 621, a plurality of detection electrodes 622 fixed to a bottom surface of the detection base plate 621, and an elastic piece 623 fixedly arranged below the detection base plate 621. A gap is reserved between the elastic piece 623 and each detection electrode 622.

The controller 9 is configured to obtain thickness deviation information of a wafer through calculation according to capacitance generated by the detection electrodes 622 when the elastic piece 623 generates deformation while pressing the wafer.

Specifically, in some other embodiments, the thicknesses of the wafers may be detected through in-situ detection or detected using a distance sensor. The former has the shortcomings of high device cost and high requirement on light. The latter has the shortcoming of insufficient detection precision. Therefore, in embodiments of the invention, a detection method using detection electrodes 622 is designed. According to the method in this embodiment, the ejector pins 611 are driven to move up and down by a high-precision electric linear module so as to ensure that the wafers are accurately lifted to the detection position. In addition, the elastic piece 623 is pressed by a top surface of the ejector pins 611 to generate an upward protruding deformation, thus a distance between an upper surface of the elastic piece 623 and the detection electrodes 622 is changed, allowing the elastic piece 623 and the detection electrodes 622 to form a film capacitance detector. The distance between the upper surface of the elastic piece 623 and the detection electrodes 622 affects capacitance generated by the detection electrode 622, while the wafers are lifted to a specified height under a lifting action of the ejector pins 611. A relationship between the thickness of the wafers and the capacitance of the detection electrodes 622 is pre-calibrated, such that the controller 9 can calculate the thickness deviation information of the wafers according to the capacitance generated by the detection electrodes 622.

More specifically, the elastic piece 623 is a metal elastic piece. The detection assembly 62 further includes a detector (not shown) for detecting the capacitance of the electrodes 622. The controller 9 acquires the capacitance of the detection electrodes 622 based on the detector.

More specifically, a plurality of detection electrodes 622 are arranged on the bottom surface of the detection base plate 621, such that the detection mechanism 6 can acquire thickness information of different positions of the wafers so as to analyze whether the upper surfaces of the thinned wafers are flat. In addition, the thickness deviation information is calculated based on an average value of the thickness information of different positions, effectively improving the accuracy and reliability of thickness detection.

In some preferred embodiments, the controller 9 is further configured to generate compensation thickness information according to the thickness deviation information when the thickness deviation information indicates an excessive thickness deviation, and to control the fine grinding mechanism 5 to perform fine grinding again on a corresponding wafer according to the compensation thickness information.

Specifically, it can be learned from the foregoing description that the thickness deviation of the wafers may be caused due to an abrasion factor of the device. Directly continuing the fine grinding according to a preset standard may not necessarily reduce the thicknesses of the wafers to a value within the preset thickness range. Therefore, according to the wafer thinning system in embodiments of the invention, the thickness deviation information is analyzed to generate the compensation thickness information, and the compensation thickness information compensates processing parameters of secondary fine grinding. That is, a stroke of the fine grinding mechanism 5 is increased based on the compensation thickness information, so as to ensure that the thicknesses of the wafers can be thinned to a value within the preset thickness range, thereby improving the fine grinding effect.

More specifically, in embodiments of the invention, excessively large thickness deviation information means that the thicknesses exceed the preset thickness range. The compensation thickness information may be equivalent to thickness deviation information or may be determined based on a difference between the thickness deviation information and an upper limit of the thickness tolerance.

In some preferred embodiments, the first conveying mechanism 2 and the second conveying mechanism 8 are both preferably roller conveyors. The first conveying mechanism 2 is preferably formed by a three-section roller conveyor.

In some preferred embodiments, the wafer thinning system further includes limiting mechanisms 10. The limiting mechanisms 10 are respectively arranged below the rough grinding mechanism 4, the fine grinding mechanism 5 and the detection mechanism 6. In this embodiment, the wafer thinning system implements stepping conveying for the carrying mechanisms 7 through the first conveying mechanism 2 and the limiting mechanisms 10.

Specifically, the limiting mechanisms 10 each preferably include a limiting and elevating mechanism 101, a limiting plate 102 and a sensing probe (not shown). The limiting plate 102 can move up and down under lifting driving of the limiting and elevating mechanism 101. The limiting plate 102 is provided with the sensing probe for detecting whether the carrying mechanisms 7 are conveyed in place. The sensing probe is preferably a sensing switch arranged on a surface of the limiting plate 102.

More specifically, in this embodiment, when the carrying mechanisms 7 are conveyed by the first conveying mechanism 2, the limiting and elevating mechanisms 101 drive the limiting plates 102 to extend out to reach a conveying surface of the first conveying mechanism 2 so as to limit an advancing position of the carrying mechanisms 7. The sensing probes are used to determine whether the carrying mechanisms 7 at stations are conveyed in place, thereby ensuring that the carrying mechanisms 7 can smoothly and accurately reach the stations.

In some preferred embodiments, the wafer thinning system further includes two lifting assemblies 11 that are arranged below the rough grinding mechanism 4 and the fine grinding mechanism 5, respectively, and are configured to lift the carrying mechanisms 7 on the first conveying mechanism 2 to implement rough grinding in cooperation with the rough grinding mechanism 4 and to implement fine grinding in cooperation with the fine grinding mechanism 5, respectively.

Specifically, if the first conveying mechanism 2 is directly used to support the carrying mechanisms 7 to implement thinning, the first conveying mechanism 2 will receive an excessively large pressure. Therefore, the service life of the first conveying mechanism 2 will be quickly shortened after long-time use, and the carrying mechanisms 7 are also likely to have position offset, affecting the thinning effect. Therefore, the wafer thinning system in embodiments of the invention is provided with the lifting assemblies 11, such that when the carrying mechanisms 7 reach a position below the rough grinding mechanism 4 or the fine grinding mechanism 5, the lifting assemblies 11 are used to lift the carrying mechanisms 7 for rough grinding or fine grinding. Moreover, after processing is completed, the lifting assemblies 11 are used to return the carrying mechanisms 7 to the first conveying mechanism 2 for continuing the conveying.

More specifically, the lifting assemblies 11 each include a lifting driving mechanism 111 and a lifting plate 112 driven to move up and down by the lifting driving mechanism 111. The first conveying mechanism 2 is provided with an avoidance groove for the lifting plates 112 to pass through.

In some preferred embodiments, the wafer thinning system further includes blowing assemblies 12. The blowing assemblies 12 are arranged on one sides of the lifting assemblies 11. The controller 9 is configured to control the blowing assemblies 12 to blow the lifting assemblies 11 that are not in a lifting state.

Specifically, during wafer thinning, powder generated by grinding may be left on the first conveying mechanism 2, may fly onto the lifting plates 112 of the lifting assemblies 11 and thus affects the levelness of the carrying mechanisms 7 placed on the lifting plates 112, thereby affecting the wafer thinning effect. Therefore, the wafer thinning system in embodiments of the invention is provided with the blowing assemblies 12 for blowing the lifting assemblies 11 that are not in a lifting state (that is, a state in which a height of the lifting plate 112 is lower than a height of the conveying surface of the first conveying mechanism 2), so as to ensure that the lifting assemblies 11 maintain a clean and tidy surface before lifting the carrying mechanisms 7, and thus appropriate thinning is guaranteed.

In some preferred embodiments, the carrying mechanisms 7 each include an electronic tag 73. The detection mechanism 6 includes a tag editor 13. The rough grinding mechanism 4 includes a tag recognizer 14.

The controller 9 is further configured to mark an electronic tag 73 of a carrying mechanism 7 on which a wafer having a thickness exceeding the preset thickness range is located based on the tag editor 13, so as to allow the rough grinding mechanism 4 to skip rough grinding by recognizing the electronic tag 73 based on the tag recognizer 14.

Specifically, in this embodiment, the rough grinding mechanism 4 determines whether the wafers on the carrying mechanisms 7 are returned wafers by analyzing data of the electronic tag 73, effectively simplifying a control logic of the controller 9 and reducing analysis load of the controller 9.

In some preferred embodiments, the fine grinding mechanism 5 also includes a tag recognizer 14. The controller 9 is further configured to mark an electronic tag 73 of a carrying mechanism 7 on which a wafer having a thickness exceeding the preset thickness range is located based on the tag editor 13 and write compensation thickness information, so as to allow the rough grinding mechanism 5 to perform fine grinding again on the corresponding wafer according to the compensation thickness information.

Specifically, in this embodiment, the compensation thickness information is written into the electronic tag 73, such that the fine grinding mechanism 5 can precisely grind the wafer that needs secondary fine grinding according to the compensation thickness information, effectively simplifying a control logic of the controller 9 and reducing analysis load of the controller 9.

In some preferred embodiments, the first transfer mechanism 1 is in consistence with the second transfer mechanism 3. The first transfer mechanism 1 includes an elevating assembly and a bidirectional conveying mechanism. The elevating assembly is configured to drive the bidirectional conveying mechanism to move up and down such that one end of the bidirectional conveying mechanism connects to the first conveying mechanism 2 or the second conveying mechanism 8.

Specifically, the bidirectional conveying mechanism is preferably a roller conveyor based on bidirectional motor driving and capable of conveying the carrying mechanisms 7 forwards or backwards.

More specifically, in this embodiment, the second conveying mechanism 8 is arranged below the first conveying mechanism 2 in parallel. The elevating assembly changes a height of the bidirectional conveying mechanism such that the bidirectional conveying mechanism switches between a state of being connected to the first conveying mechanism 2 or a state of being connected to the second conveying mechanism 8.

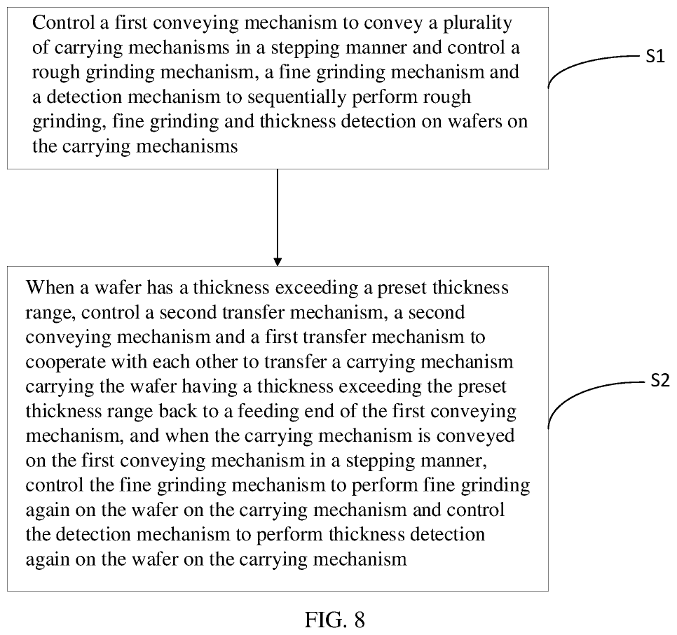

According to a second aspect, referring to FIG. 8, some embodiments of the invention further provide a thinning method of a wafer thinning system. The thinning method is applied to the wafer thinning system. The wafer thinning system includes a first transfer mechanism 1, a first conveying mechanism 2 and a second transfer mechanism 3 arranged in sequence, as well as a rough grinding mechanism 4, a fine grinding mechanism 5 and a detection mechanism 6 that are arranged in sequence on the first conveying mechanism 2. The wafer thinning system further includes a plurality of carrying mechanisms 7 for carrying wafers, and a second conveying mechanism 8 having a head end and a tail end connected to the first transfer mechanism 1 and the second transfer mechanism 3.

The thinning method includes the following steps.

S1. Control the first conveying mechanism 2 to convey the plurality of carrying mechanisms 7 in a stepping manner and control the rough grinding mechanism 4, the fine grinding mechanism 5 and the detection mechanism 6 to sequentially perform rough grinding, fine grinding and thickness detection on the wafers on the carrying mechanisms 7.

S2. When a wafer has a thickness exceeding a preset thickness range, control the second transfer mechanism 3, the second conveying mechanism 8 and the first transfer mechanism 1 to cooperate with each other to transfer a carrying mechanism 7 carrying the wafer having a thickness exceeding the preset thickness range back to a feeding end of the first conveying mechanism 2, and when the carrying mechanism 7 is conveyed on the first conveying mechanism 2 in a stepping manner, control the fine grinding mechanism 5 to perform fine grinding again on the wafer on the carrying mechanism 7 and control the detection mechanism 6 to perform thickness detection again on the wafer on the carrying mechanism 7.

The thinning method of a wafer thinning system in embodiments of the invention can implement rough grinding, fine grinding and thickness detection in sequence for the wafers on the carrying mechanisms 7, and thus the wafers are continuously thinned. In addition, when a wafer has a thickness exceeding the preset thickness range, the wafer is returned to the feeding end of the first conveying mechanism 2 through a returning function achieved under the cooperation of the second transfer mechanism 3, the second conveying mechanism 8 and the first transfer mechanism 1, such that the wafer on the carrying mechanism 7 undergoes secondary fine grinding, so as to increase the yield of wafer thinning.

In conclusion, the embodiments of the invention provide the wafer thinning system and the thinning method. The wafer thinning system is provided with the rough grinding mechanism 4, the fine grinding mechanism 5 and the detection mechanism 6 in sequence on the first conveying mechanism 2, such that the wafers on the plurality of carrying mechanisms 7 conveyed in a stepping manner by the first conveying mechanism 2 can undergo rough grinding, fine grinding and thickness detection in sequence, and thus the wafers are continuously thinned. In addition, when a wafer has a thickness exceeding the preset thickness range, the wafer is returned to the feeding end of the first conveying mechanism 2 through a returning function achieved under the cooperation of the second transfer mechanism 3, the second conveying mechanism 8 and the first transfer mechanism 1, such that the wafer on the carrying mechanism 7 undergoes secondary fine grinding, so as to increase the yield of wafer thinning.

In the description of this specification, the description with reference to the terms such as “an implementation”, “some implementations”, “exemplary implementations”, “examples”, “specific examples”, or “some examples” means that the specific features, structures, materials or characteristics described with reference to the implementations or examples are involved in at least one implementation or example of the invention. In this specification, the illustrative description of these terms does not necessarily refer to same implementations or examples. Furthermore, the specific features, structures, materials, or characteristics described may be combined in a suitable manner in any one or more implementations or examples.

The descriptions above are just some implementations of the invention. For those skilled in the art, a number of variations and improvements can also be made without departing from the spirit of the invention, and those all fall within the scope of protection of the invention.

What is claimed is:

1. A wafer thinning system, wherein the wafer thinning system comprises a first transfer mechanism, a first conveying mechanism and a second transfer mechanism arranged in sequence, as well as a rough grinding mechanism, a fine grinding mechanism and a detection mechanism that are arranged in sequence on the first conveying mechanism;
the wafer thinning system further comprises a plurality of carrying mechanisms for carrying wafers, a second conveying mechanism having a head end and a tail end connected to the first transfer mechanism and the second transfer mechanism, and a controller;
the controller is configured to control the first conveying mechanism to convey the plurality of carrying mechanisms in a stepping manner and control the rough grinding mechanism, the fine grinding mechanism and the detection mechanism to sequentially perform rough grinding, fine grinding and thickness detection on the wafers on the carrying mechanisms; and
the controller is further configured to control, when a wafer has a thickness exceeding a preset thickness range, the second transfer mechanism, the second conveying mechanism and the first transfer mechanism to cooperate with each other to transfer a carrying mechanism carrying the wafer having a thickness exceeding the preset thickness range back to a feeding end of the first conveying mechanism, and to control the fine grinding mechanism to perform fine grinding again on the wafer on the carrying mechanism and control the detection mechanism to perform thickness detection again on the wafer on the carrying mechanism when the carrying mechanism is conveyed on the first conveying mechanism in a stepping manner.

2. The wafer thinning system according to claim 1, wherein the detection mechanism comprises a jacking and separating assembly and a detection assembly; and
the jacking and separating assembly is configured to jack and separate the wafers on the carrying mechanisms located in the detection mechanism for thickness detection of the wafers in cooperation with the detection assembly.

3. The wafer thinning system according to claim 2, wherein the carrying mechanisms are each provided with a plurality of through holes; the jacking and separating assembly comprises a plurality of ejector pins capable of passing through the through holes and a first elevating mechanism configured to drive the ejector pins to move up and down; and
the controller is configured to control the first elevating mechanism to drive the ejector pins to move up to separate the wafers according to preset height information, so as to allow the detection assembly to measure thickness deviation information of the wafers.

4. The wafer thinning system according to claim 2, wherein the detection assembly comprises a detection base plate, a plurality of detection electrodes fixed to a bottom surface of the detection base plate, and an elastic piece fixedly arranged below the detection base plate; a gap is reserved between the elastic piece and the detection electrodes; and
the controller is configured to obtain thickness deviation information of the wafers through calculation according to capacitance generated by the detection electrodes when the elastic piece generates deformation while pressing the wafer.

5. The wafer thinning system according to claim 3, wherein the controller is further configured to generate compensation thickness information according to the thickness deviation information when the thickness deviation information indicates an excessive thickness deviation, and to control the fine grinding mechanism to perform fine grinding again on a corresponding wafer according to the compensation thickness information.

6. The wafer thinning system according to claim 4, wherein the controller is further configured to generate compensation thickness information according to the thickness deviation information when the thickness deviation information indicates an excessive thickness deviation, and to control the fine grinding mechanism to perform fine grinding again on a corresponding wafer according to the compensation thickness information.

7. The wafer thinning system according to claim 1, wherein the wafer thinning system further comprises two lifting assemblies that are arranged below the rough grinding mechanism and the fine grinding mechanism, respectively, and are configured to lift the carrying mechanisms on the first conveying mechanism to implement rough grinding in cooperation with the rough grinding mechanism and to implement fine grinding in cooperation with the fine grinding mechanism, respectively.

8. The wafer thinning system according to claim 7, wherein the wafer thinning system further comprises blowing assemblies; the blowing assemblies are arranged on one sides of the lifting assemblies; and the controller is configured to control the blowing assemblies to blow the lifting assemblies that are not in a lifting state.

9. The wafer thinning system according to claim 1, wherein the carrying mechanisms each comprise an electronic tag; the detection mechanism comprises a tag editor; the rough grinding mechanism comprises a tag recognizer; and
the controller is further configured to mark an electronic tag of the carrying mechanism on which the wafer having a thickness exceeding the preset thickness range is located based on the tag editor, so as to allow the rough grinding mechanism to skip rough grinding by recognizing the electronic tag based on the tag recognizer.

10. The wafer thinning system according to claim 1, wherein the first transfer mechanism is in consistence with the second transfer mechanism; the first transfer mechanism comprises an elevating assembly and a bidirectional conveying mechanism; and the elevating assembly is configured to drive the bidirectional conveying mechanism to move up and down such that one end of the bidirectional conveying mechanism connects to the first conveying mechanism or the second conveying mechanism.

11. A thinning method of a wafer thinning system, wherein the thinning method is applied to the wafer thinning system; the wafer thinning system comprises a first transfer mechanism, a first conveying mechanism and a second transfer mechanism arranged in sequence, as well as a rough grinding mechanism, a fine grinding mechanism and a detection mechanism that are arranged in sequence on the first conveying mechanism; and the wafer thinning system further comprises a plurality of carrying mechanisms for carrying wafers, and a second conveying mechanism having a head end and a tail end connected to the first transfer mechanism and the second transfer mechanism;
the thinning method comprises the following steps:
controlling the first conveying mechanism to convey the plurality of carrying mechanisms in a stepping manner and controlling the rough grinding mechanism, the fine grinding mechanism and the detection mechanism to sequentially perform rough grinding, fine grinding and thickness detection on the wafers on the carrying mechanisms; and
when a wafer has a thickness exceeding a preset thickness range, controlling the second transfer mechanism, the second conveying mechanism and the first transfer mechanism to cooperate with each other to transfer a carrying mechanism carrying the wafer having a thickness exceeding the preset thickness range back to a feeding end of the first conveying mechanism, and controlling the fine grinding mechanism to perform fine grinding again on the wafer on the carrying mechanism and controlling the detection mechanism to perform thickness detection again on the wafer on the carrying mechanism when the carrying mechanism is conveyed on the first conveying mechanism in a stepping manner.
